(19) United States
(12) Patent Application Publication
(10) Pub. No.: US 2017/0194192 A1
(43) Pub. Date: Jul. 6, 2017

(54) METAL FILLING AND PLANARIZATION OF RECESSED FEATURES

(71) Applicant: Tokyo Electron Limited, Tokyo (JP)

(72) Inventor: Kai-Hung Yu, Watervliet, NY (US)

(21) Appl. No.: 15/391,154

(22) Filed: Dec. 27, 2016

Related U.S. Application Data
(60) Provisional application No. 62/273,793, filed on Dec. 31, 2015.

(51) Int. Cl. H01L 21/768; H01L 23/532; H01L 21/3213; H01L 21/02; H01L 21/321

(52) U.S. Cl. CPC H01L 21/7684; H01L 21/76882; H01L 21/02244; H01L 21/3212; H01L 21/32133; H01L 21/76883; H01L 21/76843; H01L 21/76871; H01L 23/53252

(57) ABSTRACT

Embodiments of the invention provide a method for metal filling and planarization of a recessed feature in a substrate. According to one embodiment the method includes providing the substrate containing the recessed feature below a planar surface of the substrate, filling the recessed feature with a metal layer, the metal layer forming excess metal above the recessed feature, oxidizing the excess metal by electrochemical oxidation to form an oxidized metal layer above the planar surface of the recessed feature, and removing the oxidized metal layer by chemical mechanical planarization (CMP). According to another embodiment, the method includes, following the filling, performing a cyclical electrochemical oxidation and etching process that at least substantially removes the excess metal layer above the planar surface of the recessed feature.

### CROSS-REFERENCE TO RELATED APPLICATIONS

This application is related to and claims priority to U.S. Provisional Patent Application No. 62/273,793, filed Dec. 31, 2015, the entire contents of which are herein incorporated by reference.

### FIELD OF INVENTION

The present invention relates to methods for void-less metal filling and planarization of features in microelectronic devices.

### BACKGROUND OF THE INVENTION

An integrated circuit contains various semiconductor devices and a plurality of conducting metal paths that provide electrical power to the semiconductor devices and allow these semiconductor devices to share and exchange information. Within the integrated circuit, metal layers are stacked on top of one another using intermetal or interlayer dielectric layers that insulate the metal layers from each other.

Normally, each metal layer must form an electrical contact to at least one additional metal layer. Such electrical contact is achieved by etching a feature (i.e., a via) in the interlayer dielectric that separates the metal layers, and filling the resulting via with a metal to create an interconnect. Metal layers typically occupy etched pathways in the interlayer dielectric. A “via” normally refers to any feature such as a hole, line or other similar feature formed within a dielectric layer that provides an electrical connection through the dielectric layer to a conductive layer underlying the dielectric layer. Similarly, metal layers connecting two or more vias are normally referred to as trenches.

The use of copper (Cu) metal in multilayer metallization schemes for manufacturing integrated circuits creates problems due to high mobility of Cu atoms in dielectrics, such as SiO₂, and Cu atoms may create electrical defects in silicon (Si). Thus, Cu metal layers, Cu filled trenches, and Cu filled vias are normally encapsulated with a barrier material to prevent Cu atoms from diffusing into the dielectrics and Si. Barrier layers are normally deposited on trench and via sidewalls and bottoms prior to Cu seed deposition, and may include materials that are preferably non-reactive and immiscible in Cu, provide good adhesion to the dielectrics and can offer low electrical resistivity.

An increase in device performance is normally accompanied by a decrease in device area or an increase in device density. An increase in device density requires a decrease in via dimensions used to form interconnects, including a larger aspect ratio (i.e., depth to width ratio). As via dimensions decrease, and aspect ratios increase, it becomes increasingly more challenging to form diffusion barrier layers with adequate thickness on the sidewalls of the vias, while also providing enough volume for the metal layer in the via. In addition, as via and trench dimensions decrease and the thicknesses of the layers in the vias and trenches decrease, the material properties of the layers and the layer interfaces become increasingly more important. In particular, the processes forming those layers need to be carefully integrated into a manufacturable process sequence where good control is maintained for all the steps of the process sequence.

The problems associated with the use of Cu metal in increasingly smaller features on a substrate will require replacing the Cu metal with other low-resistivity metals. Filling of these features with the low-resistivity metals requires overfilling the recessed features and removing excess metal from above the recessed features. Difficulties involving removing the excess metal include formation of recesses in the substrate material between the metal filled features.

### SUMMARY OF THE INVENTION

Methods for void-less metal filling and planarization of features for microelectronic devices are described in several embodiments.

Embodiments of the invention provide a method for metal filling and planarization of a recessed feature in a substrate. According to one embodiment the method includes providing the substrate containing the recessed feature below a planar surface of the substrate, filling the recessed feature with a metal layer, the metal layer forming excess metal above the recessed feature, oxidizing the excess metal by electrochemical oxidation to form an oxidized metal layer above the planar surface of the recessed feature, and removing the oxidized metal layer by chemical mechanical planarization (CMP). According to another embodiment, the method includes, following the filling, performing a cyclical electrochemical oxidation and etching process that at least substantially removes the excess metal layer above the planar surface of the recessed feature.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A-1F schematically show through cross-sectional views a method for metal filling and planarization of a recessed feature according to an embodiment of the invention;

FIGS. 2A-2C schematically show through cross-sectional views a method for metal filling and planarization of a recessed feature according to another embodiment of the invention;

FIGS. 3A-3B schematically show through cross-sectional views a method for metal filling and planarization of a recessed feature according to an embodiment of the invention;

FIG. 4 schematically shows a processing system for performing cyclical electrochemical oxidation and etching according to an embodiment of the invention;

FIG. 5 schematically shows a processing system for performing simultaneous electrochemical oxidation and CMP according to an embodiment of the invention; and

FIG. 6 shows an example of cyclically varying the voltage of a working electrode to perform cyclical electrochemical oxidation and etching according to an embodiment of the invention.

### DETAILED DESCRIPTION OF SEVERAL EMBODIMENTS

Methods for void-less metal filling and planarization of features for microelectronic devices are described in several embodiments. The methods include oxidizing a metal layer using electrochemical oxidation, and thereafter removing the oxidized metal layer. The oxidized metal layer is easier to remove by etching or CMP than the metal layer. In one example, an oxidized Ru metal layer may be removed by CMP at a rate that is about 10× faster than for a Ru metal layer.

According to one embodiment, the method includes providing a substrate containing a recessed feature below a planar surface of the substrate, filling the recessed feature with a metal layer and forming excess metal above the recessed feature, oxidizing the excess metal by electrochemical oxidation to form an oxidized metal layer above the planar surface of the substrate, and removing the oxidized metal layer by CMP. The filling may be performed by depositing the metal layer on the substrate, including in the recessed feature, heat-treating the substrate to reflow the metal layer, thereby filling the recessed feature with the metal and forming the excess metal above the recessed feature. According to one embodiment, the removing forms a metal fill in the recessed feature, the metal fill having an upper surface that is at least substantially co-planar with the planar surface with the substrate. According to one embodiment, the method further includes repeating the oxidizing and removing at least once to form a metal fill in the recessed feature, the metal fill having an upper surface that is at least substantially co-planar with the planar surface with the substrate. In one example, the oxidation and the removing have temporal overlap. In another example, the oxidation and the removing are performed simultaneously.

According to one embodiment, the method includes providing a substrate containing a recessed feature below a planar surface of the substrate, depositing a metal layer on the substrate, including in the recessed feature, filling the recessed feature with the metal layer and forming excess metal above the recessed feature, performing a cyclical electrochemical oxidation and etching process that at least substantially removes the excess metal layer above the planar surface of the recessed feature. The filling may be performed by depositing the metal layer on the substrate, including in the recessed feature, heat-treating the substrate to reflow the metal layer, thereby filling the recessed feature with the metal and forming the excess metal above the recessed feature. According to one embodiment, the performing forms a metal fill in the recessed feature, the metal fill having an upper surface that is at least substantially co-planar with the planar surface with the substrate.

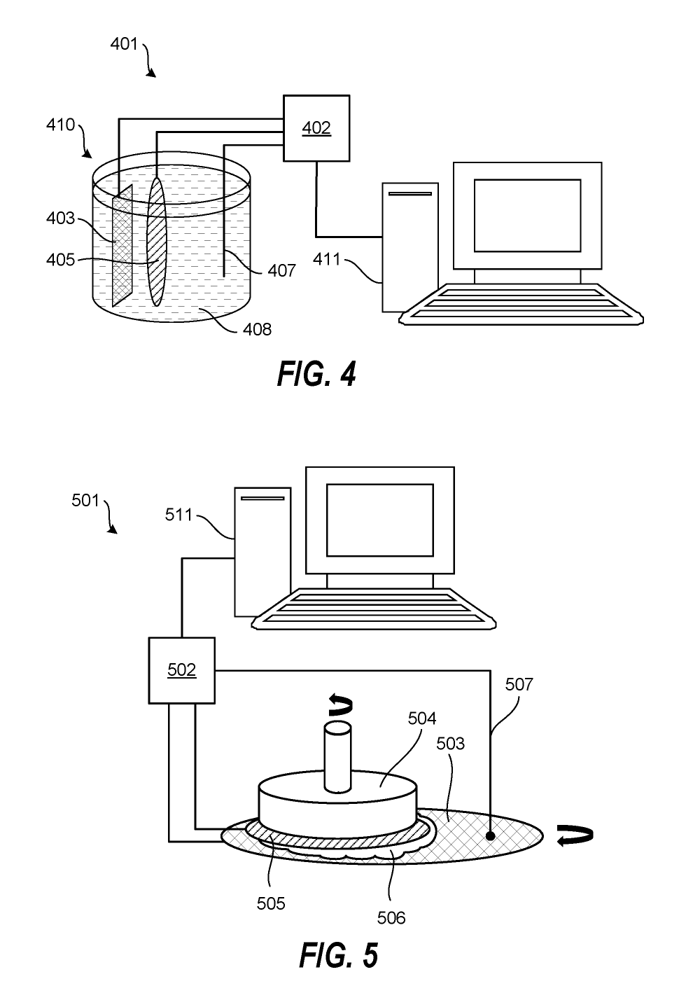

FIG. 4 schematically shows a processing system 401 for performing cyclical electrochemical oxidation and etching according to an embodiment of the invention. The processing system 401 includes an electrochemical cell 410 containing an electrochemical solution 408, a reference electrode 407, a counter electrode 403, and a substrate (wafer) which serves as the working electrode 405. All the electrodes are immersed in the electrochemical solution 408. A potentiostat 402 controls the voltage difference between the working electrode 405 and the reference electrode 407 and measures the current between the working electrode 405 and the counter electrode 403. The processing system 401 may further include an oscillator (not shown) for cyclically varying the voltage difference between the working electrode 405 and the reference electrode 407. The counter electrode 403 is generally an inert conductor like platinum or graphite and completes the cell circuit. A computer 411 is configured to control the potentiostat 402.

FIG. 5 schematically shows a processing system for performing simultaneous cyclical electrochemical oxidation and CMP according to an embodiment of the invention. The processing system 501 includes a computer 511, a potentiostat 502 that controls the voltage difference between the working electrode 505 (substrate) and the reference electrode 507. The processing system 501 further includes a counter electrode 503 (polishing pad), a polishing chuck 504, and a polishing slurry 506.

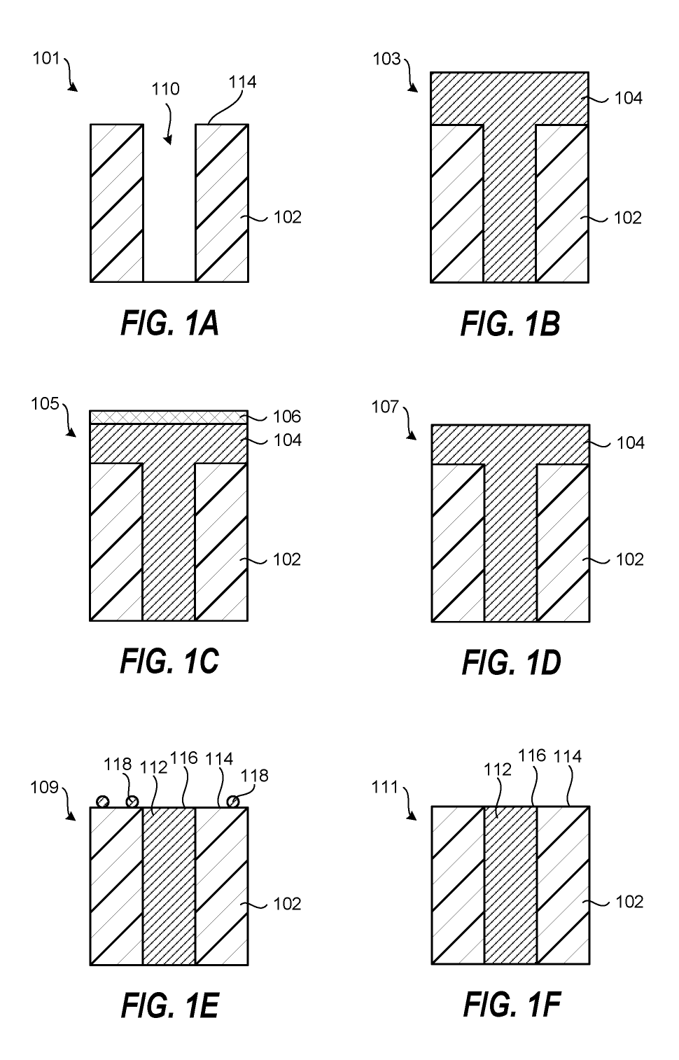

FIGS. 1A-1F schematically show through cross-sectional views a method for metal filling and planarization of a recessed feature according to an embodiment of the invention.

In FIG. 1A, the structure 101 includes a recessed feature 110 below a planar surface 114 of a substrate 102. The recessed feature 110 can for example include a trench or a via. A diameter of the recessed feature 110 can be less than 30 nm, less than 20 nm, less than 10 nm, or less than 5 nm. The diameter can be between 20 nm and 30 nm, between 10 nm and 20 nm, between 5 nm and 10 nm, or between 3 nm and 5 nm. A depth of the recessed feature 110 can, for example, be greater 20 nm, greater than 50 nm, greater than 100 nm, or greater than 200 nm. The recessed feature 110 can, for example, have an aspect ratio (AR, depth:width) between 2:1 and 20:1, between 2:1 and 10:1, or between 2:1 and 5:1. In one example, the substrate 102 includes a dielectric layer and the recessed feature 110 is formed in the dielectric layer. Although not shown in FIG. 1A, a barrier layer or a liner may be formed on the sidewalls of the recessed feature 110.

As depicted by the structure 103 of FIG. 1B, the recessed feature 110 may be filled with a metal layer 104. According to one embodiment of the invention, the metal layer 104 may be selected from the group consisting of ruthenium (Ru), iridium (Ir), osmium (Os), palladium (Pd), cobalt (Co), tungsten (W), titanium (Ti), and combinations thereof. According to another embodiment, the metal layer 104 may contain a metal-containing material selected from the group consisting of TiN, MoN, TaN, and WN.

The filling of the recessed feature 110 may be performed by depositing a metal layer 104 on the substrate 102, including in the recessed feature 110. The deposition of the metal layer 104 can include heat-treating the substrate 102 to reflow the metal layer 104, thereby filling the recessed feature 110 with the metal layer 104 and forming the excess metal above the recessed feature 110.

According to embodiments of the invention, the heat-treating may, for example, be performed at a substrate temperature between 200° C. and 600° C., between 300° C. and 400° C., between 500° C. and 600° C., between 400° C. and 450° C., or between 450° C. and 500° C. Further, the heat-treating may be performed at below atmospheric pressure in the presence of Ar gas, H₂ gas, or both Ar gas and H₂ gas. In one example, the heat-treating may be performed at below atmospheric pressure in the presence of forming gas. In another example, the heat-treating may be formed under high-vacuum conditions without flowing a gas into a process chamber used for the heat-treating.

According to one embodiment, the heat-treating may be performed in the presence of a gaseous plasma. The use of a gaseous plasma may be used for lowering the heat-treating temperature compared to when a gaseous plasma is not employed. This allows the use of heat-treating temperatures that are compatible with low-k and ultra-low-k materials. According to some embodiments, the recessed feature 110 may be formed in a low-k material with 2.5≦k<3.9 or an ultra-low-k material with k<2.5. In one example, the gaseous plasma can include Ar gas. The plasma conditions may be selected to include low-energy Ar ions.

According to some embodiments, the metal layer 104 may be deposited by atomic layer deposition (ALD), chemical vapor deposition (CVD), plating, or sputtering. In one example, the metal layer 104 may be a Ru metal layer that is deposited by CVD using Ru₃(CO)₁₂ and CO carrier gas. However, other Ru metal precursors may be used to deposit the Ru metal layer. In some examples, the Ru metal layer may include a Ru-containing alloy.

According to another embodiment, prior to depositing the metal layer 104, the substrate 102 may be exposed to a treatment gas that modifies the surfaces in the recessed feature 110 and increases the nucleation rate of the metal layer 104 in the recessed feature 110. In one example, the treatment gas can include a nitrogen plasma, an NH₃ plasma, an NH₃ anneal, or a combination thereof. The exposure to the treatment gas can nitride the surfaces in the recessed feature 110. In one example, the treatment gas increases the hydrophilicity of the substrate and thereby increases the nucleation rate of the metal layer 104 in the recessed feature 110.

In one example, the opening of a recessed feature 110 may pinch off (close) and a void may form inside the recessed feature 110 before the recessed feature 110 is completely filled with the metal layer 104. According to one embodiment, the void may be removed by removing excess metal from above the recessed feature 110, for example by a planarization process, thereby removing the metal that caused the pinch off. Thereafter, a heat-treating process may be performed to reflow the metal layer 104 in the recessed feature 110. According to one embodiment, this may be followed by depositing an additional metal layer on reflowed metal layer and repeating the heat-treating process to achieve void-free filling of the recessed feature 110.

In one example, prior to metal deposition, a TaN nucleation layer was deposited in a recessed feature 110 using ALD with alternating exposures of tert-butylimido-tris-ethylmethylamido-tantalum (TBEMT, Ta(NCMe₃)(NEtMe)₃) and ammonia (NH₃) gas at a substrate temperature of about 350° C. Thereafter, a Ru metal layer with a thickness of 70 Å was deposited on the TaN nucleation layer using CVD with Ru₃(CO)₁₂ and CO carrier gas at a substrate temperature of about 200° C. According to some embodiments, the nucleation layer may be deposited by ALD CVD. The nucleation layer can, for example, include a nitride material. According to one embodiment, the nucleation layer may be selected from the group consisting of Mo, MoN, Ta, TaN, W, WN, Ti, and TiN. A role of the nucleation layer is to provide a good nucleation and adhesion surface for the metal (e.g., Ru metal) in the recessed feature 110 to ensure conformal deposition of the metal (e.g., Ru metal) with a short incubation time. Unlike when using a Cu metal fill, a good barrier layer may not be required between the dielectric material and Ru metal. Therefore, in the case of a Ru metal fill, the nucleation layer can be very thin and may be non-continuous or incomplete with gaps that expose the dielectric material in the recessed feature 110. This allows for increasing the amount of Ru metal in a feature fill compared to a Cu metal feature fill. In some examples, a thickness of the nucleation layer can be 20 Å or less, 15 Å or less, 10 Å or less, or 5 Å or less.

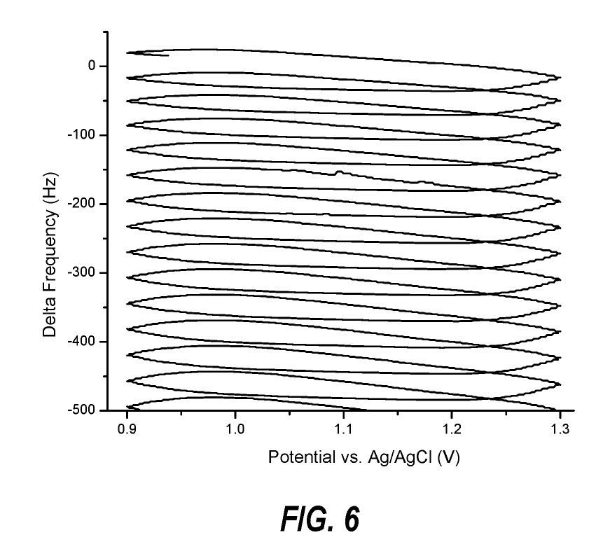

According to one embodiment, the method further includes performing a cyclical electrochemical oxidation and etching process that in each cycle oxidizes and removes the excess metal above the planar surface 114 of the substrate 102. This is schematically shown by structures 105 and 107 in FIGS. 1C and 1D, respectively. FIG. 1C shows formation of an oxidized metal layer 106 following electrochemical oxidation, and FIG. 1D shows complete removal of the excess metal by etching. Referring also to FIG. 4, in one example, for a Ru metal layer 104, the cyclical electrochemical oxidation and etching process may be performed by cyclically varying the voltage of the working electrode 405 between about 0.9 and 1.3 Volts (vs. Ag/AgCl reference electrode 407), resulting in a Ru etching rate of about 2 Å/cycle. FIG. 6 shows an example of cyclically varying the voltage of a working electrode 405 between about 0.9 and 1.3 Volts (vs. Ag/AgCl reference electrode).

FIG. 1E schematically shows a structure 109 following the cyclical electrochemical oxidation and etching process that removes the excess metal above the planar surface 114 of the substrate 102. A metal fill 112 is formed in the recessed feature 110, where the metal fill 112 has an upper surface 116 that is at least substantially co-planar with the planar surface 114 of the substrate 102. FIG. 1E further shows oxidized metal residue 118 that may be present following the cyclical electrochemical oxidation and etching process. If needed, the oxidized metal residue 118 may be removed using CMP, followed by a cleaning process to remove any residue. The resulting clean structure 111 is shown in FIG. 1F.

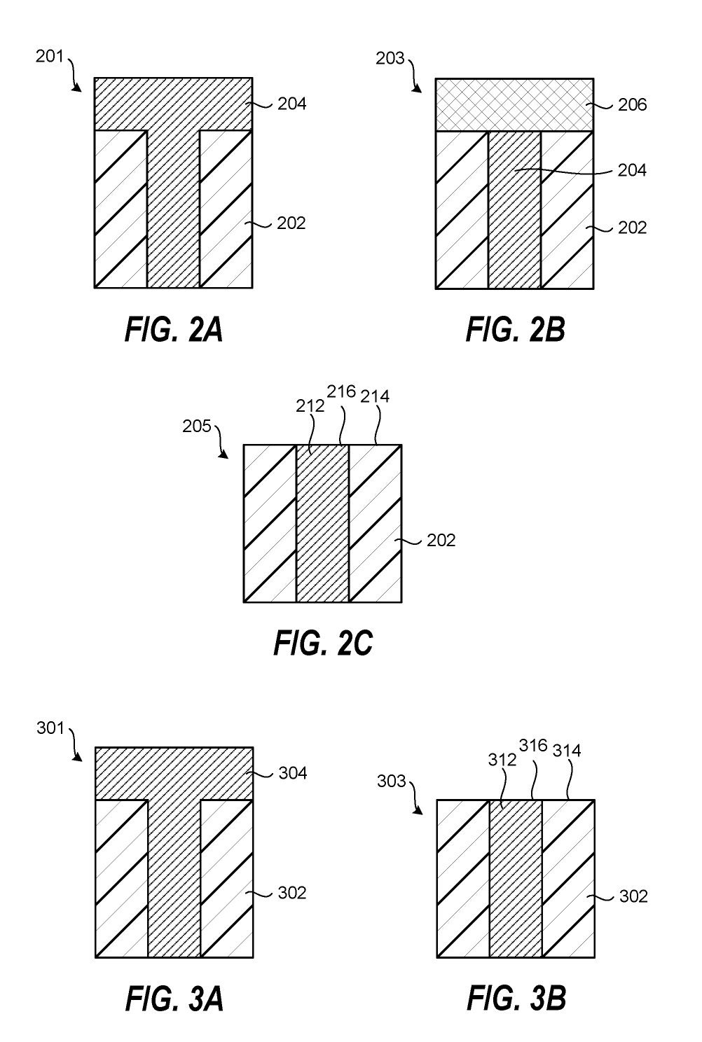

FIGS. 2A-2C schematically show through cross-sectional views a method for metal filling and planarization of a recessed feature according to another embodiment of the invention. FIG. 2A shows a structure 201 that contains a substrate 202 and a metal layer 204 that fills a recessed feature in a substrate 202 and forms excess metal above the recessed feature.

FIG. 2B shows a structure 203 following a process of oxidizing the excess metal by electrochemical oxidation to form an oxidized metal layer 206 above the planar surface of the recessed feature. In one example, for a Ru metal layer 204, an oxidized Ru metal layer 206 may be formed by applying between 1.3 and 1.5 Volts for a few minutes to the substrate 202 (working electrode). For example, a 35 nm thick oxidized Ru metal layer may be formed by applying 1.4 Volts for 3 min. Thus, an oxidized Ru metal layer with a thickness greater than 30 nm may easily be obtained.

FIG. 2C shows a structure 205 after removing the oxidized metal layer 206 by CMP. A metal fill 212 is formed in the recessed feature, where the metal fill 212 has an upper surface 216 that is at least substantially co-planar with the planar surface 214 of the substrate 202.

FIGS. 3A-3B schematically show through cross-sectional views a method for metal filling and planarization of a recessed feature according to an embodiment of the invention. FIG. 3A shows a structure 301 that contains a substrate 302 and a metal layer 304 that fills a recessed feature in a substrate 302 and forms excess metal above the recessed feature. The structure 301 is exposed to a process that includes oxidizing the excess metal by electrochemical oxidation to form an oxidized metal layer above the planar surface of the recessed feature, and simultaneously removing the oxidized metal layer by CMP. The processing system 501 in FIG. 5 may be used for performing the simultaneous electrochemical oxidation and CMP. In one example, for a Ru metal layer, an oxidized Ru metal layer (not shown) may be formed by applying between 1.3 and 1.5 Volts to the substrate (working electrode) while simultaneously rotating the counter electrode 503 (polishing pad) and/or the polishing chuck 504 to remove the oxidized Ru metal layer. The resulting structure 303 is shown in FIG. 3B and contains a metal fill 312 is formed in the recessed feature, where the metal fill 312 has an upper surface 316 that is at least substantially co-planar with the planar surface 314 of the substrate 302. According to one embodiment, the removing forms a metal fill in the recessed feature, the metal fill having an upper surface that is at least substantially co-planar with the planar surface with the substrate.

A plurality of embodiments for void-less metal filling and planarization of features for microelectronic devices have been described in several embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. It is therefore intended that the scope of the invention be limited not by this detailed description, but rather by the claims appended hereto.

What is claimed is:

1. A method for metal filling and planarization of a recessed feature in a substrate, the method comprising:
providing the substrate containing the recessed feature below a planar surface of the substrate;
filling the recessed feature with a metal layer, the metal layer forming excess metal above the recessed feature;
oxidizing the excess metal by electrochemical oxidation to form an oxidized metal layer above the planar surface of the recessed feature; and
removing the oxidized metal layer by chemical mechanical planarization (CMP).

2. The method of claim 1, wherein the filling includes
depositing the metal layer on the substrate, including in the recessed feature; and
heat-treating the substrate to reflow the metal layer, thereby filling the recessed feature with the metal and forming the excess metal above the recessed feature.

3. The method of claim 1, further comprising
repeating the oxidizing and removing at least once to form a metal fill in the recessed feature, the metal fill having an upper surface that is at least substantially co-planar with the planar surface with the substrate.

4. The method of claim 1, wherein the removing forms a metal fill in the recessed feature, the metal fill having an upper surface that is at least substantially co-planar with the planar surface with the substrate.

5. The method of claim 1, wherein the oxidation and the removing have temporal overlap.

6. The method of claim 1, wherein the oxidation and the removing are performed simultaneously.

7. The method of claim 1, wherein the metal layer is selected from the group consisting of ruthenium (Ru), iridium (Ir), osmium (Os), palladium (Pd), cobalt (Co), tungsten (W), titanium (Ti), and combinations thereof.

8. The method of claim 1, wherein the metal layer is selected from the group consisting of TiN, MoN, TaN, WN, and combinations thereof.

9. A method for metal filling and planarization of a recessed feature in a substrate, the method comprising:
providing the substrate containing the recessed feature below a planar surface of the substrate;
filling the recessed feature with a metal layer, the metal layer forming excess metal above the recessed feature; and
performing a cyclical electrochemical oxidation and etching process that at least substantially removes the excess metal layer above the planar surface of the recessed feature.

10. The method of claim 9, wherein the filling includes
depositing the metal layer on the substrate, including in the recessed feature; and
heat-treating the substrate to reflow the metal layer, thereby filling the recessed feature with the metal and forming the excess metal above the recessed feature.

11. The method of claim 9, wherein the performing forms a metal fill in the recessed feature, the metal fill having an upper surface that is at least substantially co-planar with the planar surface with the substrate.

12. The method of claim 9, wherein the metal layer is selected from the group consisting of ruthenium (Ru), iridium (Ir), osmium (Os), palladium (Pd), cobalt (Co), tungsten (W), titanium (Ti), and combinations thereof.

13. The method of claim 9, wherein the metal layer is selected from the group consisting of TiN, MoN, TaN, WN, and combinations thereof.

14. A method for Ru metal filling and planarization of a recessed feature in a substrate, the method comprising:
providing the substrate containing the recessed feature below a planar surface of the substrate;
filling the recessed feature with a Ru metal layer, the Ru metal layer forming excess metal above the recessed feature
performing a cyclical electrochemical oxidation and etching process that at least substantially removes the excess Ru metal layer above the planar surface of the recessed feature.

15. The method of claim 14, wherein the filling includes
depositing the Ru metal on the substrate, including in the recessed feature; and
heat-treating the substrate to reflow the Ru metal layer, thereby filling the recessed feature with the Ru metal and forming the excess Ru metal above the recessed feature.

16. The method of claim 14, further comprising:
prior to depositing the Ru metal layer, forming a nucleation layer in the recessed feature.

17. The method of claim 16, wherein the nucleation layer is selected from the group consisting of Mo, MoN, Ta, TaN, W, WN, Ti, and TiN.

18. The method of claim 14, wherein the performing forms a Ru metal fill in the recessed feature, the Ru metal fill having an upper surface that is at least substantially co-planar with the planar surface with the substrate.

19. The method of claim 14, wherein the Ru metal layer is deposited by atomic layer deposition (ALD), chemical vapor deposition (CVD), plating, or sputtering.

20. The method of claim 14, wherein the substrate includes a dielectric layer and the feature is formed in the dielectric layer.
